(19) United States
(12) Patent Application Publication
(10) Pub. No.: US 2026/0323937 A1
(43) Pub. Date: Oct. 15, 2026

(54) MEMORY DEVICE, MANUFACTURING METHOD THEREOF, AND TRANSISTOR

(71) Applicant: WUHAN XINXIN SEMICONDUCTOR MANUFACTURING CO., LTD., WUHAN, (CN)

(72) Inventor: KAIWEI CAO, WUHAN (CN)

(21) Appl. No.: 19/571,503

(22) Filed: Mar. 19, 2026

(30) Foreign Application Priority Data
Apr. 10, 2025 (CN) 202510450133.7

(51) Int. Cl. H10B 41/30; H10B 41/20; H10D 30/01; H10D 30/68

(52) U.S. Cl. CPC H10B 41/30; H10B 41/20; H10D 30/0411; H10D 30/6894

(57) ABSTRACT

A memory device, a manufacturing method thereof, and a transistor are provided. The memory device includes: a semiconductor substrate, including a memory region; a plurality of first trenches, defined in the semiconductor substrate; a gate insulating layer and a semi-floating gate, arranged in a corresponding one of the first trenches; a plurality of second trenches, defined in the semiconductor substrate, where each of the second trenches is disposed above multiple first trenches, and each of the second trenches is in communication with multiple first trenches disposed in a same row along a first direction; a first isolation layer, arranged at sidewalls of a corresponding one of the second trenches; an inter-gate dielectric layer and a control gate, arranged in a corresponding one of the second trenches in the memory region. In a second direction, a width of the control gate is less than a width of the semi-floating gate.

### CROSS REFERENCE TO RELATED APPLICATIONS

The present disclosure claims priority of Chinese Patent Application No. 202510450133.7, filed on Apr. 10, 2025, the entire contents of which are hereby incorporated by reference in their entireties.

### TECHNICAL FIELD

The present disclosure relates to the field of semiconductor technologies, and in particular to a memory device, a manufacturing method of the memory device, and a transistor.

### BACKGROUND

In an application of an integrated circuit, performances of various semiconductor devices may be influenced by thickness of different material layers, resulting in affecting a performance of a memory device.

During practical operations, a researcher of the present disclosure may discover that during a current manufacturing process of the memory device, when the thickness of different material layers meets one performance requirement, it may fail to meet another performance requirement, thereby affecting an overall performance of the memory device.

### SUMMARY OF THE DISCLOSURE

According to a first aspect, some embodiments of the present disclosure provide a memory device. The memory device includes a semiconductor substrate, including a memory region; a plurality of first trenches, defined in the semiconductor substrate; a gate insulating layer and a semi-floating gate, arranged in a corresponding one of the first trenches; a plurality of second trenches, defined in the semiconductor substrate, where each of the second trenches is disposed above multiple first trenches, and each of the second trenches is in communication with multiple first trenches disposed in a same row along a first direction; a first isolation layer, arranged at sidewalls of a corresponding one of the second trenches; and an inter-gate dielectric layer and a control gate, arranged in the corresponding one of the second trenches in the memory region; where in a second direction, a width of the control gate is less than a width of the semi-floating gate.

According to a second aspect, some embodiments of the present disclosure provide a manufacturing method of a memory device. The manufacturing method includes: manufacturing method of a memory device, including: providing a semiconductor substrate, where the semiconductor substrate includes a memory region; forming a plurality of first trenches and a plurality of second trenches, where the plurality of first trenches and the plurality of second trenches are disposed in the semiconductor substrate, each of the second trenches is disposed above multiple first trenches, and each of the second trenches is in communication with multiple first trenches disposed in a same row along a first direction; forming a gate insulating layer and a semi-floating gate in each of the first trenches; and forming a first isolation layer at sidewalls of each of the second trenches, and forming an inter-gate dielectric layer and a control gate in each of the second trenches; where in a second direction, a width of the control gate is less than a width of the semi-floating gate.

According to a third aspect, some embodiments of the present disclosure is to provide a transistor. The transistor includes a semiconductor substrate; a gate insulating layer and a semi-floating gate, arranged in the semiconductor substrate; an inter-gate dielectric layer and a control gate, arranged in the semiconductor substrate and disposed above the semi-floating gate, where the control gate is isolated from the semi-floating gate by the inter-gate dielectric layer; and a first isolation layer, arranged at sidewalls of the control gate; where in a second direction, a width of the control gate is less than a width of the semi-floating gate.

### BRIEF DESCRIPTION OF THE DRAWINGS

To illustrate the technical solutions more clearly in the embodiments of the present disclosure, the following will be briefly described in the description of the embodiments required to use the attached drawings. It is obvious that the following description of the attached drawings are only some of the embodiments of the present disclosure, and those skilled in the art, without creative work, can also obtain other attached drawings based on these drawings.

FIG. 1 is a three-dimensional structural schematic view from a first perspective of a memory device according to some embodiments of the present disclosure.

FIG. 2 is a three-dimensional structural schematic view from a second perspective of the memory device according to some embodiments of the present disclosure.

FIG. 3 is a three-dimensional structural schematic view from a third perspective of the memory device according to some embodiments of the present disclosure.

FIG. 4 is a flow chart of a manufacturing method of a memory device according to some embodiments of the present disclosure.

FIG. 5 is a schematic structural view of a semiconductor substrate according to some embodiments of the present disclosure.

FIG. 6A is a three-dimensional structural schematic view from a first perspective of forming a plurality of first trenches and a plurality of second trenches according to some embodiments of the present disclosure.

FIG. 6B is a schematic view from a second perspective of FIG. 6A according to some embodiments of the present disclosure.

FIG. 6C is a schematic view from a third perspective of FIG. 6A according to some embodiments of the present disclosure.

FIG. 7 is a schematic structural view of forming a gate insulating layer and a first gate material according to some embodiments of the present disclosure.

FIG. 8A is a three-dimensional structural schematic view from a first perspective of forming a contact window according to some embodiments of the present disclosure.

FIG. 8B is a schematic view from a second perspective of FIG. 8A according to some embodiments of the present disclosure.

FIG. 8C is a schematic view from a third perspective of FIG. 8A according to some embodiments of the present disclosure.

FIG. 9 is a three-dimensional structural schematic view from a first perspective of forming a second gate material according to some embodiments of the present disclosure.

FIG. 10 is a three-dimensional structural schematic view from a first perspective of forming a semi-floating gate according to some embodiments of the present disclosure.

FIG. 11 is a three-dimensional structural schematic view from a first perspective of forming a first isolation layer according to some embodiments of the present disclosure.

FIG. 12A is a three-dimensional structural schematic view from a first perspective of removing a first isolation material on the semi-floating gate according to some embodiments of the present disclosure.

FIG. 12B is a schematic structural view of a first region shown in FIG. 12A according to some embodiments of the present disclosure.

FIG. 12C is a schematic structural view of a second region shown in FIG. 12A according to some embodiments of the present disclosure.

FIG. 12D is a schematic structural view of a third region shown in FIG. 12A according to some embodiments of the present disclosure.

FIG. 12E is a schematic structural view of a fourth region shown in FIG. 12A according to some embodiments of the present disclosure.

FIG. 13 is a top view shown in FIG. 12A according to some embodiments of the present disclosure.

FIG. 14 is a three-dimensional structural schematic view from a first perspective of forming an inter-gate dielectric layer and a control gate according to some embodiments of the present disclosure.

FIG. 15 is a three-dimensional structural schematic view from a first perspective of forming a second isolation layer according to some embodiments of the present disclosure.

FIG. 16 is a three-dimensional structural schematic view from a fourth perspective of removing at least part of a first sub-dielectric layer and at least part of the second isolation layer in the memory region according to some embodiments of the present disclosure.

FIG. 17A is a three-dimensional structural schematic view from a first perspective of forming source/drain according to some embodiments of the present disclosure.

FIG. 17B is a schematic view from a second perspective of FIG. 17A according to some embodiments of the present disclosure.

FIG. 18A is a schematic structural view from a first perspective of a transistor according to some embodiments of the present disclosure.

FIG. 18B is a schematic structural view from a second perspective of the transistor according to some embodiments of the present disclosure.

Reference numerals: 10, memory device; 20, transistor; 100, semiconductor substrate; 110, isolation structure; 101, first trench; 102, second trench; 1021, second sub-trench; 103, third trench; 200, gate structure; 210, gate insulating layer; 220, semi-floating gate; 221, first gate; 2211, first gate material; 222, second gate; 2221, second gate material; 230, inter-gate dielectric layer; 240, control gate; 241, third gate material; 250, lead-out line; 300, first isolation layer; 310, first isolation material; 400, second isolation layer; 500, first dielectric layer; 510, first sub-dielectric layer; 520, second sub-dielectric layer; S/D, source/drain; S, source; D, drain; A, memory region; B, lead-out region; C1, active area; F, first spare region; E1, first region; E2, second region; E3, third region; E4, fourth region; K, contact window; K1, width of the second gate in a first direction; K2, width of the first gate in the first direction.

### DETAILED DESCRIPTION

Technical solutions in the embodiments of the present disclosure will be clearly and completely described below by referring to the accompanying drawings of the embodiments. Obviously, the described embodiments are only some of but not all of the embodiments of the present disclosure. Based on the embodiments of the present disclosure, all other embodiments obtained by any ordinary skilled person in the art without creative work shall fall within the scope of the present disclosure.

A memory device may be provided, such that it may be possible to effectively reduce electrical leakage and breakdown between a control gate and a source/drain, thereby improving the performance of a semiconductor device.

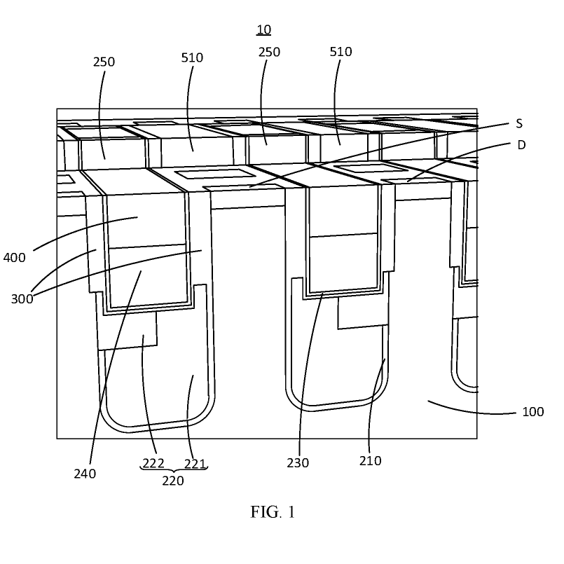

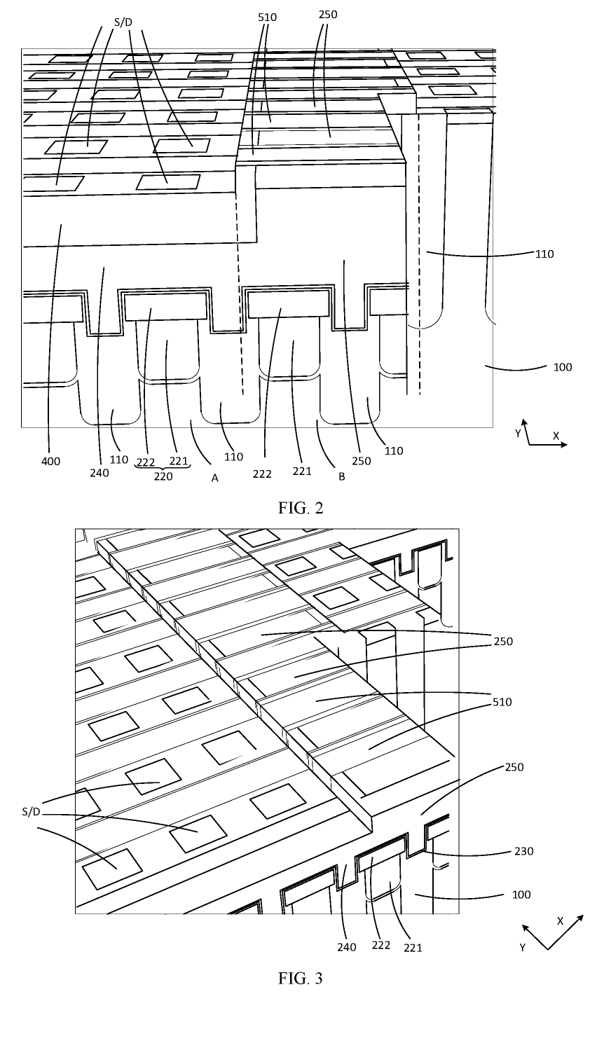

As shown in FIGS. 1, 2 and 3, FIG. 1 is a three-dimensional structural schematic view from a first perspective of a memory device according to some embodiments of the present disclosure. FIG. 2 is a three-dimensional structural schematic view from a second perspective of the memory device according to some embodiments of the present disclosure. FIG. 3 is a three-dimensional structural schematic view from a third perspective of the memory device according to some embodiments of the present disclosure.

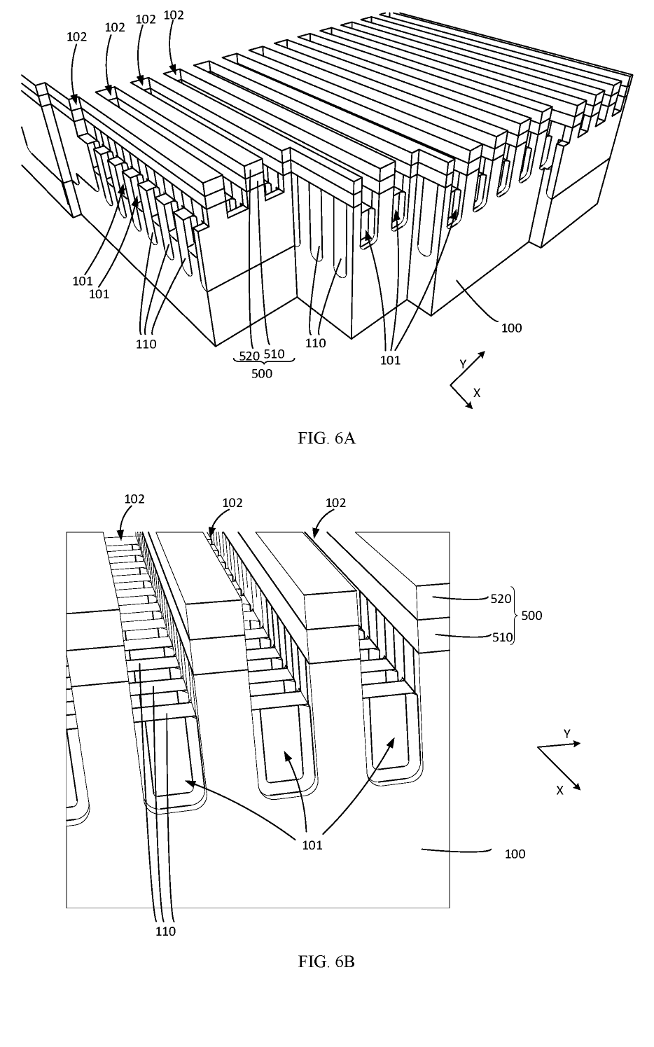

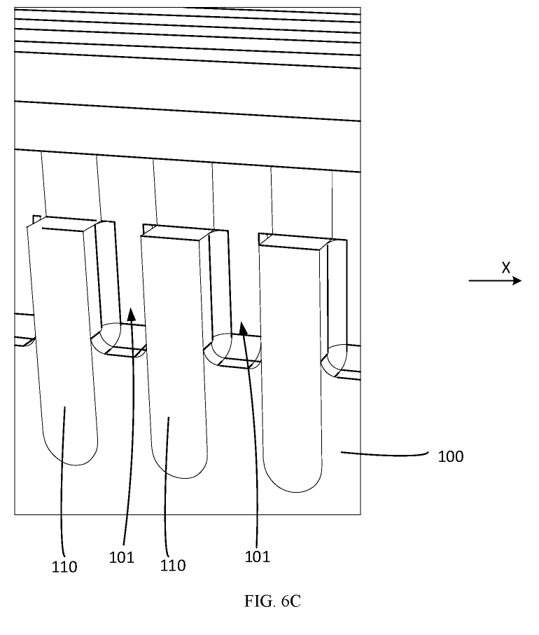

As shown in FIGS. 1, 2 and 3, the memory device 10 provided by the embodiments of the present disclosure may include: a semiconductor substrate 100, including a memory region A; a plurality of first trenches 101 (as shown in FIG. 6A), defined in the semiconductor substrate 100; a gate insulating layer 210 and a semi-floating gate 220, arranged/formed in a corresponding one of the first trenches 101; a plurality of second trenches 102 (as shown in FIG. 6A), defined in the semiconductor substrate 100, where each of the second trenches 102 may be disposed above multiple first trenches 101 (i.e., multiple of the plurality of first trenches 101, a number of the plurality of first trenches 101, or several of the plurality of first trenches 101), and each of the second trenches 102 may be in communication with multiple first trenches 101 disposed in a same row along a first direction; a first isolation layer 300, arranged at sidewalls of a corresponding one of the second trenches 102; an inter-gate dielectric layer 230 and a control gate 240, arranged in the corresponding one of the second trenches in the memory region A. In a second direction, a width of the control gate 240 may be less than a width of a semi-floating gate 220.

The first direction may be a X-direction. A second direction may be a Y-direction. The first direction and the second direction may be perpendicular to each other on a horizontal plane.

The semiconductor substrate 100 may be any suitable substrate known in the art. In some embodiments, the semiconductor substrate may be at least one of the following materials: silicon (Si), germanium (Ge), silicon-germanium (SiGe), silicon carbide (SiC), silicon-germanium-carbon (SiGeC), indium arsenide (InAs), gallium arsenide (GaAs), indium phosphide (InP) or other III/V compound semiconductors. The semiconductor substrate may also include multi-layer structures including the above-mentioned semiconductors. Alternatively, the semiconductor substrate may also silicon-on-insulator (SOI), silicon-on-silicon-insulator (SSOI), silicon-germanium-on-silicon-insulator (S-SiGeOI), silicon-germanium-on-insulator (SiGeOI), or germanium-on-insulator (GeOI).

In some embodiments, a first isolation layer 400 may be disposed at sidewalls of the corresponding one of the second trenches, such that the width of the control gate may be less than the width of a semi-floating gate. Therefore, it may be possible to ensure a distance between the control gate and the source/drain, such that it may be possible to effectively reduce leakage and breakdown between the control gate and the source/drain.

A material of the first isolation layer 300 may be an oxide material, such as silicon oxide.

In some embodiments, a thickness of the first isolation layer 300 may be set according to actual conditions. The thickness of the first isolation layer 300 may be in a range from 50 A to 300 A, for example, 50 A, 100 A, 150 A, 200 A, 300 A, etc. A may be angstrom, and 1 A may be equal to 10⁻¹⁰ meters, i.e., 0.1 nanometers.

In some embodiments, a plurality of isolation structures 110 may be arranged in the semiconductor substrate 100. The plurality of isolation structures 110 may extend along the second direction, such that the semiconductor substrate 100 may include a plurality of active areas, which may refer to a subsequent drawing for details, as shown in FIG. 5.

In some embodiments, the source/drain S/D may be arranged in the semiconductor substrate 100 disposed at two sides of a gate structure 200 in the second direction.

In some embodiments, the gate structure 200 may include the gate insulating layer 210, the semi-floating gate 220, the inter-gate dielectric layer 230 and the control gate 240. The gate insulating layer 210 may cover at least part of a sidewall of the corresponding one of the first trenches 101. The semi-floating gate 220 may be arranged in the corresponding one of the first trenches 101. The first isolation layer 300 may be disposed at the sidewalls of the corresponding one of the second trenches 102. The inter-gate dielectric layer 230 may cover the semi-floating gate 220 and the sidewalls of the corresponding one of the second trenches 102. The control gate 240 may be arranged in the corresponding one of the second trenches 102. That is, the control gate 240 may be disposed on the semi-floating gate 220. In a second direction, the width of the control gate 240 may be less than the width of a semi-floating gate 220.

In the embodiments, the first isolation layer may be disposed at the sidewalls of the corresponding one of the second trenches, such that the width of the control gate may be less than the width of the semi-floating gate. Therefore, it may be possible to ensure a distance between the control gate and the source/drain, such that it may be possible to effectively reduce leakage and breakdown between the control gate and the source/drain. In addition, on the premise of ensuring the distance and reducing leakage, instead of increasing a thickness of an inter-gate dielectric layer to ensure a certain distance between the control gate and the source/drain, it may be possible to ensure a thickness of the inter-gate dielectric layer to be relatively thinner, such that it may be possible to maintain a coupling rate of the memory device, thereby improving the performance of a semiconductor transistor.

In some embodiments, the semiconductor substrate 100 may further include a lead-out region B. The gate insulating layer 210 and the semi-floating gate 220 may be arranged/formed in the corresponding one of the first trenches 101 disposed in the lead-out region B. The inter-gate dielectric layer 230 and a lead-out line 250 may be arranged in the corresponding one of the second trenches 102. A top surface of the lead-out line 250 may be higher than the top surface of the semiconductor substrate 100 in the memory region A. The lead-out line 250 may be connected to a plurality of control gates 240 disposed in the same row along the first direction.

The first isolation layer 300 may be further arranged at the sidewalls of the corresponding one of the second trenches 102, and the sidewalls of the second trenches 102 may be disposed at two sides of the lead-out line 250 located in the lead-out region B.

In some embodiments, the semiconductor substrate 100 may include the memory region A and the lead-out region B. The plurality of first trenches 101 may be distributed in the memory region A and the lead-out region B. The plurality of second trenches 102 may extend along the first direction and across/traverse the memory region A and the lead-out region B. Each of the second trenches 102 may be disposed above multiple first trenches 101, and each of the second trenches 102 may be in communication with multiple first trenches 101 disposed in the same row along the first direction. The gate insulating layer 210 and the semi-floating gate 220 may be arranged in the corresponding one of the first trenches 101. The first isolation layer 300 may be arranged at the sidewalls of the corresponding one of the second trenches 102 in the memory region A. The inter-gate dielectric layer 230 and the control gate 240 may be arranged in the corresponding one of the second trenches 102. The inter-gate dielectric layer 230 may be in contact with the semi-floating gate 220. In some embodiments, the first isolation layer 300 may be arranged in the corresponding one of the second trenches 102 disposed in the lead-out region B. The inter-gate dielectric layer 230 and the lead-out line 250 may be arranged in the corresponding one of the second trenches 102. The lead-out line 250 may be connected to the plurality of control gates 240 disposed in the same row along the first direction.

In some embodiments, the memory device 10 may further include a first sub-dielectric layer 510. The first sub-dielectric layer 510 may be arranged on the semiconductor substrate 100 disposed at two sides of the lead-out lines 250. A top surface of the first sub-dielectric layer 510 and the top surface of the lead-out lines 250 may be disposed on a same plane. A plurality of lead-out lines 250 disposed in the second direction may be isolated from each other by the first sub-dielectric layer 510.

The first sub-dielectric layer 510 may be a nitride layer, such as a silicon nitride layer.

In some embodiments, in the lead-out region B, the plurality of lead-out lines 250 may be arranged at intervals in the second direction. The first sub-dielectric layer 510 may be arranged between adjacent two of the plurality of lead-out lines 250, such that the plurality of lead-out lines 250 disposed in the second direction may be isolated from each other by the first sub-dielectric layer 510. In addition, there may be no first sub-dielectric layer 510 in the memory region A, or the first sub-dielectric layer 510 arranged in the memory region A may be removed.

In some embodiments, the memory device 10 may further include a second isolation layer 400, the second isolation layer 400 may be arranged on the control gate 240 disposed in the second trenches 102 defined in the memory region A. The second isolation layer 400 may be in contact with the control gate 240, and a bottom surface of the second isolation layer 400 may be lower than the top surface of the semiconductor substrate 100.

A material of the second isolation layer 400 may be the same as that of the first isolation layer 300, i.e., an oxide material such as silicon oxide. Alternatively, the material of the second isolation layer 400 may be different from that of the first isolation layer 300.

In some embodiments, the second isolation layer 400 may be arranged in the corresponding one of the second trenches 102 defined in the memory region A. The second isolation layer 400 may cover the control gate 240.

In some embodiments, a plurality of semi-floating gates 220 disposed in the same row along the first direction may be isolated from each other by the plurality of isolation structures 110 disposed in the semiconductor substrate 100. A top surface of each of the semi-floating gates 220 may be higher than the top surface of each of the isolation structures 110 exposed by the corresponding one of the second trenches 102.

In some embodiments, the plurality of isolation structures 110 may be further arranged in the semiconductor substrate 100. The plurality of isolation structures 110 may extend along the second direction, such that the semiconductor substrate 100 may include a plurality of active areas C1. In the first direction, the plurality of isolation structures 110 may be arranged at intervals. That is, the corresponding one of the first trenches 101 may be arranged between adjacent two of the plurality of isolation structures 110, such that the plurality of semi-floating gates 220 disposed in the same row along the first direction may be isolated from each other by the plurality of isolation structures 110.

In some embodiments, the plurality of semi-floating gates 220 disposed in a same column along the second direction may be isolated from each other by the semiconductor substrate 100.

In some embodiments, the semi-floating gate 220 may include a first gate 221 and a second gate 222.

The first gate 221 may be isolated from the semiconductor substrate 100 by the gate insulating layer 210, and the second gate 222 may be in contact with the semiconductor substrate 100. In the first direction, a width of the second gate 222 may be greater than a width of the first gate 221.

In some embodiments, a gate insulating layer 210 may be arranged in the corresponding one of the first trenches 101, the first gate 221 and the second gate 222 may be arranged on the gate insulating layer 210. The first gate 221 may be isolated from the semiconductor substrate 100 by the gate insulating layer 210, the second gate 222 may be in contact with the semiconductor substrate 100, and the second gate 222 may be in contact with the first gate 221. The semi-floating gate 220 may include the first gate 221 and the second gate 222. In the first direction, the width of the second gate 222 may be greater than the width of the first gate 221.

It may be understood that a material of the first gate 221 may be different from that of the second gate 222. In some embodiments, the material of the first gate 221 may be a polycrystalline material, and the material of the second gate 222 may be a single-crystal material.

A material of the control gate 240 may be a polycrystalline material.

In some embodiments, the inter-gate dielectric layer 230 may be arranged on the semi-floating gate 220 disposed in the corresponding one of the first trenches 101, such that the inter-gate dielectric layer 230 may cover the semi-floating gate 220 and the sidewalls of the corresponding one of the second trenches 102, and thus the control gate 240 may be arranged on the inter-gate dielectric layer 230 in the memory region A. That is, the control gate 240 may be arranged in the corresponding one of the second trenches 102 defined in the memory region A, and then the second isolation layer 400 may be arranged on the control gate 240, so as to fill the corresponding one of the second trenches 102.

In some embodiments, the lead-out line 250 may be arranged in the second trenches 102 disposed in the lead-out region B. Therefore, the lead-out line 250 disposed in the lead-out region B may be connected to the plurality of control gates 240 disposed in the memory region A. That is, each of the lead-out lines 250 may be connected to the plurality of control gates 240 disposed in the same row along the first direction.

In some embodiments, a plurality of source/drain S/D may be further arranged on the memory device 10. In the memory region A, the plurality of source/drain may be arranged in the active areas C1 disposed at two sides of the gate structure 200 in the second direction. That is, the plurality of source/drain S/D may be arranged in the semiconductor substrate 100 disposed at two sides of the corresponding one of the first trenches 101 in the second direction.

A metal silicide may be arranged on a source S, a drain D, and the lead-out line 250, so as to reduce a contact resistance.

In the embodiments, the first isolation layer may be disposed at the sidewalls of the corresponding one of the second trenches, such that the width of the control gate may be less than the width of the semi-floating gate. Therefore, it may be possible to ensure the distance between the control gate and the source/drain, such that it may be possible to effectively reduce leakage and breakdown between the control gate and the source/drain. In addition, on the premise of ensuring the distance and reducing leakage, instead of increasing a thickness of an inter-gate dielectric layer to ensure a certain distance between the control gate and the source/drain, it may be possible to ensure a thickness of the inter-gate dielectric layer to be relatively thinner, such that it may be possible to maintain a coupling rate of the memory device, thereby improving the performance of the memory device.

A manufacturing method of a memory device may be further provided by some embodiments of the present disclosure.

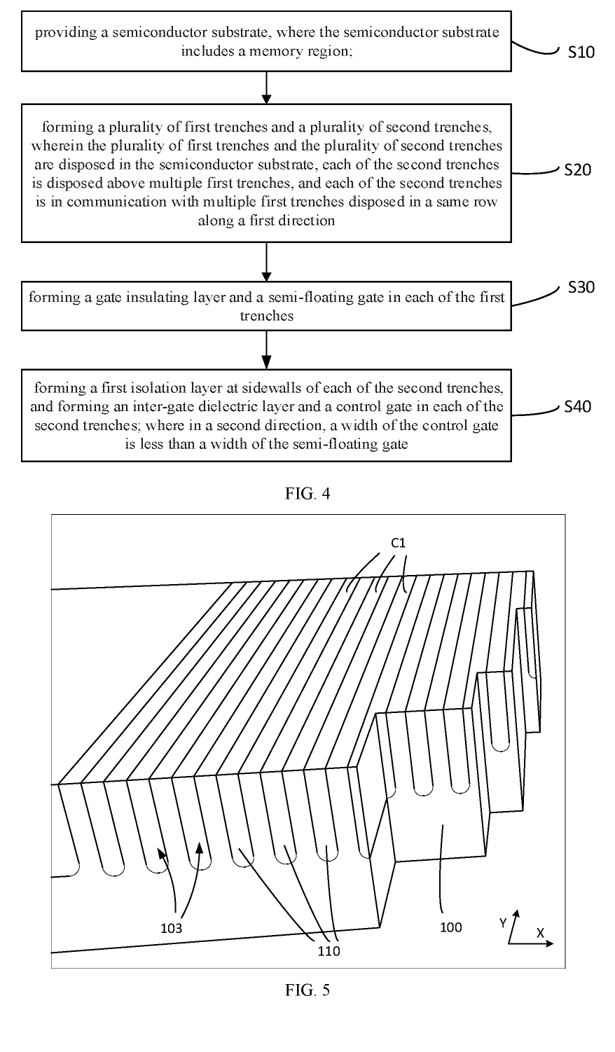

As shown in FIG. 4, FIG. 4 is a flow chart of a manufacturing method of a memory device according to some embodiments of the present disclosure.

As shown in FIG. 4, the manufacturing method of a memory device may include the following operations.

In an operation S10, a semiconductor substrate may be provided. The semiconductor substrate may include a memory region.

In some embodiments, a semiconductor substrate 100 may be provided, and the semiconductor substrate 100 may include a memory region A.

In an operation S20, a plurality of first trenches and a plurality of second trenches may be formed. The plurality of first trenches and the plurality of second trenches may be disposed in the semiconductor substrate. Each of the second trenches may be disposed above multiple first trenches. Each of the second trenches may be in communication with multiple first trenches disposed in a same row along a first direction.

The plurality of first trenches 101 may be referred to trenches formed in the semiconductor substrate 100. Multiple first trenches 101 disposed in the same row along the first direction may be isolated from each other by a plurality of isolation structures 110 in the semiconductor substrate 100, and a plurality of first trenches 101 disposed in a same column along the second direction may be isolated from each other by the semiconductor substrate 100. That is, the plurality of first trenches 101 may be distributed in the semiconductor substrate 100. The plurality of second trenches 102 may also be referred to trenches formed in the semiconductor substrate 100. Each of the second trench 102 may be disposed above multiple first trenches 101, and the plurality of second trenches 102 may extend along the first direction, such that each of the second trench 102 may be in communication with the multiple first trenches 101 disposed in the same row along the first direction. The first direction may be the X-direction.

In an operation S30, a gate insulating layer and a semi-floating gate may be formed in each of the first trenches.

The gate insulating layer 210 may be referred to an insulating layer formed on at least part of sidewalls of each of the first trenches 101. The gate insulating layer 210 may be configured to isolate the semiconductor substrate 100 from at least part of the semi-floating gate 220. The semi-floating gate 220 may be referred to a gate material formed in each of the first trenches 101 disposed in the semiconductor substrate 100.

In an operation S40, a first isolation layer may be further formed at sidewalls of each of the second trenches, and an inter-gate dielectric layer and a control gate may be formed in each of the second trenches. In a second direction, a width of the control gate may be less than a width of a semi-floating gate.

The first isolation layer 300 may be referred to an isolation layer formed on the semi-floating gate 220 and disposed at the sidewalls of each of the second trenches 102. The inter-gate dielectric layer 230 may be referred to a dielectric layer between the semi-floating gate 220 and the control gate 240. The control gate 240 may be referred to a gate material formed on the inter-gate dielectric layer 230.

In some embodiments, a thickness of the first isolation layer 300 disposed at the sidewalls of each of the second trenches may be set according to actual conditions. The thickness of the first isolation layer 300 may be in a range from 50 A to 300 A, for example, 50 A, 100 A, 150 A, 200 A, 300 A, etc. A may be angstrom, i.e., a unit of length. 1 A may be equal to 10⁻¹⁰ meters, i.e., 0.1 nanometers.

In the embodiments, the first isolation layer may be disposed at the sidewalls of each of the second trenches, such that the width of the control gate subsequently formed may be less than the width of the semi-floating gate. Therefore, it may be possible to ensure a distance between the control gate and the source/drain, such that it may be possible to effectively reduce leakage and breakdown between the control gate and the source/drain. In addition, on the premise of ensuring the distance and reducing leakage, it may be possible to ensure a thickness of the inter-gate dielectric layer to be relatively thinner, such that it may be possible to maintain a coupling rate of the memory device, thereby improving the performance of the memory device.

The manufacturing method may be described below by referring to the accompanying drawings.

The semiconductor substrate may be provided, and the semiconductor substrate may include a memory region.

As shown in FIG. 5, FIG. 5 is a schematic structural view of a semiconductor substrate according to some embodiments of the present disclosure.

As shown in FIG. 5, the semiconductor substrate 100 may be provided, and the semiconductor substrate 100 may include a memory region A. A plurality of third trenches 103 may be formed in the semiconductor substrate 100 and extend along the second direction. An isolation structure 110 may be formed in each of the third trenches 103. An active area C1 may be formed between adjacent two isolation structures 110 and extend along the second direction. That is, in the first direction, the isolation structure 110 and the active area C1 may be arranged at intervals.

In some embodiments, a plurality of isolation structures 110 may be formed in the semiconductor substrate 100 and extend along the second direction, so as to form a plurality of strip-shaped active areas C1. Therefore, the isolation structure 110 and the active area C1 arranged at intervals may be exposed on a surface of the semiconductor substrate 100.

In some embodiments, a plurality of first trenches and a plurality of second trenches may be formed.

As shown in FIGS. 6A, 6B and 6C, FIG. 6A is a three-dimensional structural schematic view from a first perspective of forming a plurality of first trenches and a plurality of second trenches according to some embodiments of the present disclosure. FIG. 6B is a schematic view from a second perspective of FIG. 6A according to some embodiments of the present disclosure. FIG. 6C is a schematic view from a third perspective of FIG. 6A according to some embodiments of the present disclosure.

As shown in FIGS. 6A, 6B and 6C, based on FIG. 5, at least part of the isolation structure 110 and at least part of the semiconductor substrate 100 may be removed, such that to a plurality of first trenches 101 and a plurality of second trenches 102 may be formed in the semiconductor substrate 100. Each of the second trenches 102 may be disposed above multiple first trenches 101. The multiple first trenches 101 disposed in the same row along the first direction may be isolated from each other by the plurality of isolation structures 110. Each of the second trenches 102 may be in communication with the multiple first trenches 101 disposed in the same row along the first direction.

In some embodiments, the semiconductor substrate 100 may be etched. An etching rate of the semiconductor substrate 100 may be greater than that of the isolation structure 110. That is, both of the at least part of the semiconductor substrate 100 and the at least part of the isolation structure 110 may be removed. Finally, in formed trenches, a trench disposed above the isolation structure 110 may be served/defined as the second trench 102, and another trench disposed below the isolation structure 110 may be served as the first trench 101. The plurality of first trenches 101 may be arranged at intervals along the first direction and isolated from each other by the plurality of isolation structures 110. Each of the second trenches 102 may be in communication with the multiple first trenches 101 disposed in the same row along the first direction.

In some embodiments, before forming the plurality of first trenches 101 and the plurality of second trenches 102, the manufacturing method may further include the following operations.

A first dielectric layer 500 may be formed to cover the semiconductor substrate 100 and the isolation structure 110. The first dielectric layer 500 may be served as a mask, and the semiconductor substrate 100 may be etched, such that the plurality of first trenches 101 and the plurality of second trenches 102 may be formed in the semiconductor substrate 100.

In some embodiments, the first dielectric layer 500 may include a first sub-dielectric layer 510 and a second sub-dielectric layer 520. The first sub-dielectric layer 510 may be a nitride layer, such as a silicon nitride layer. The second sub-dielectric layer 520 may be an oxide layer, such as a silicon oxide layer.

Next, a gate insulating layer 210 and a semi-floating gate 220 may be formed in each of the first trenches 101.

An operation of forming the gate insulating layer 210 and the semi-floating gate 220 may include the following operations.

First, the gate insulating layer 210 and a first gate material 2211 may be formed.

As shown in FIG. 7, FIG. 7 is a schematic structural view of forming a gate insulating layer and a first gate material according to some embodiments of the present disclosure.

As shown in FIG. 7, based on FIG. 6A, a gate insulating layer 210 may be formed at each of a sidewall of each of the first trenches 101 and a sidewall of each of the second trenches 102. Therefore, a first gate material 2211 may be formed in each of the first trenches 101 and each of the second trenches 102 where the gate insulating layer 210 may be formed.

Next, at least part of the first gate material 2211 and at least part of the gate insulating layer 210 may be removed, such that a contact window K may be formed.

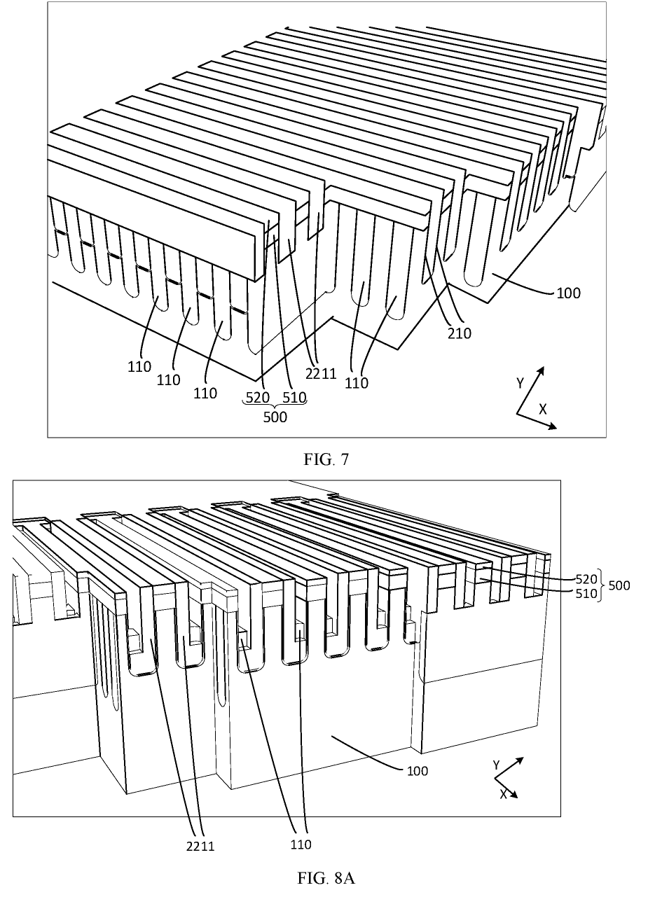

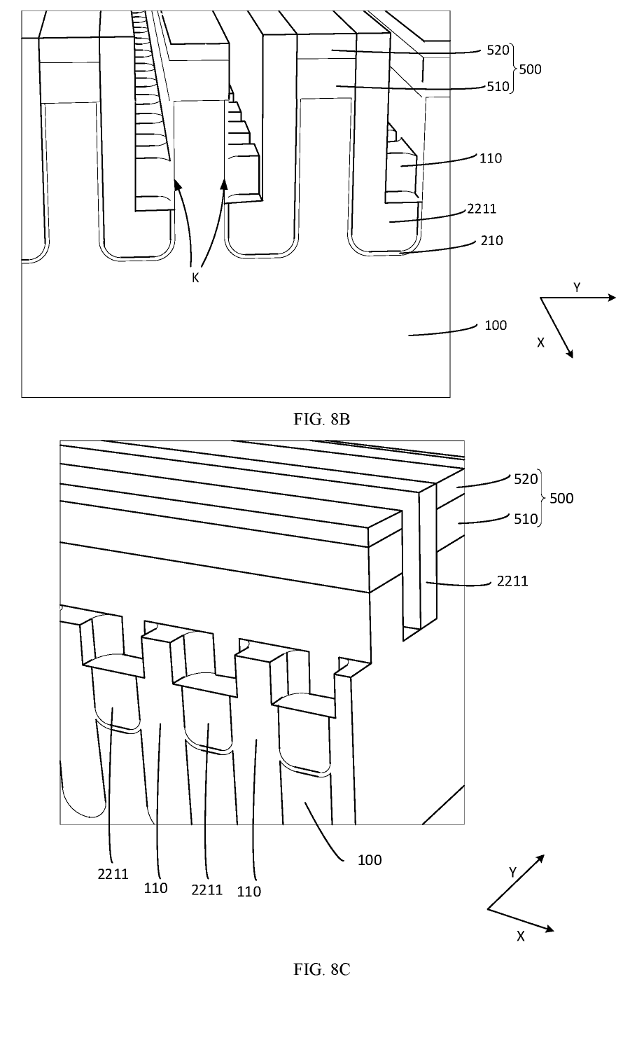

As shown in FIG. 8A, FIG. 8A is a three-dimensional structural schematic view from a first perspective of forming a contact window according to some embodiments of the present disclosure, FIG. 8B is a schematic view from a second perspective of FIG. 8A according to some embodiments of the present disclosure, and FIG. 8C is a schematic view from a third perspective of FIG. 8A according to some embodiments of the present disclosure.

As shown in FIGS. 8A, 8B and 8C based on FIG. 7, at least part of the first gate material 2211 in each of the second trenches 102 and at least part of the first gate material 2211 in each of the first trenches 101 may be removed, and at least part of the exposed gate insulating layer 210 may be removed, such that a contact window K may be formed. That is, the semiconductor substrate 100 disposed at the contact window K may be exposed.

In some embodiments, a hard mask may be configured to cover the at least part of the first gate material 2211, and the first gate material 2211 which is not covered by the hard mask may be removed. When the contact window K is formed, a top surface of the first gate material 2211 remained at the contact window may be lower than a top surface of the isolation structure 110 exposed by a corresponding one of the second trenches 102.

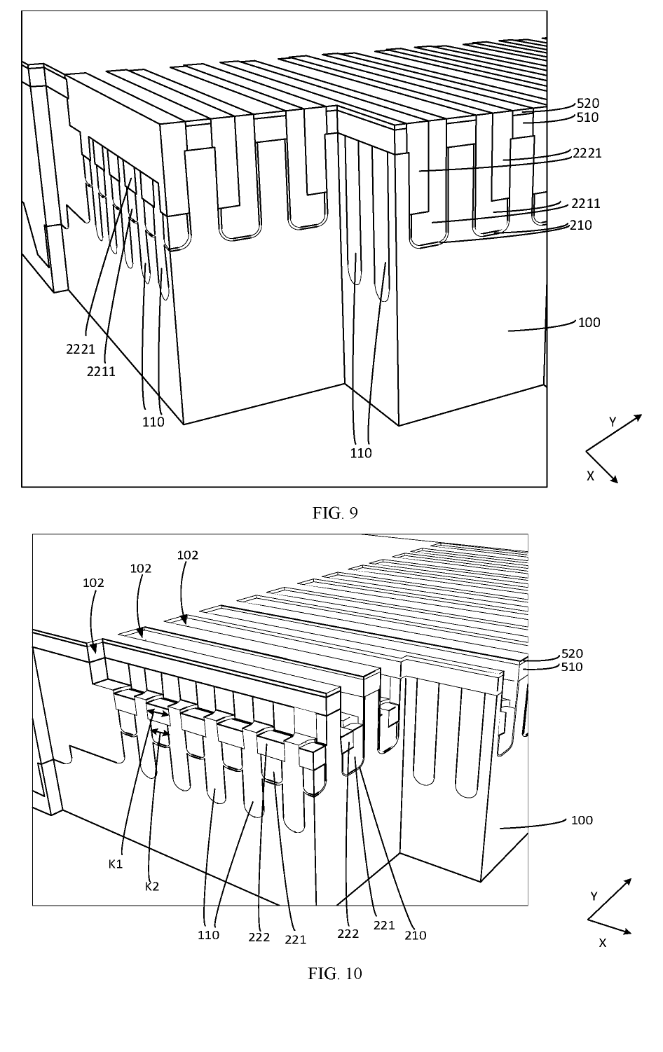

In some embodiments, when the contact window K is formed, at least part of the isolation structure 110 exposed by the corresponding one of the second trenches 102 may be further removed, such that in the first direction, a width of an exposed isolation structure may be less than a width of an isolation structure 110 between the first gate materials 2211, as shown in FIGS. 8B and 8C. In this way, in the first direction, a width K1 of the second gate subsequently formed may be greater than a width K2 of the first gate, which may be illustrated in FIG. 10 for details.

In some embodiments, a second gate material 2221 may be formed at the contact window K.

As shown in FIG. 9, FIG. 9 is a three-dimensional structural schematic view from a first perspective of forming a second gate material according to some embodiments of the present disclosure.

As shown in FIG. 9, based on FIG. 8A, a second gate material 2221 may be formed at the contact window K, and the first trenches 101 and the second trenches 102 may be refilled. The second gate material 2221 and the first gate material 2211 may be silicon but have different materials. In some embodiments, the second gate material 2221 may be a single-crystal material, and the first gate material 2211 may be a polycrystalline material. The second gate material 2221 may be formed by an epitaxial process.

In some embodiments, at least part of the first gate material 2211, at least part of the second gate material 2221, and at least part of the gate insulating layer 210 may be removed, and a first gate 221 and a second gate 222 may be formed. The semi-floating gate 220 may include the first gate 221 and the second gate 222.

As shown in FIG. 10, FIG. 10 is a three-dimensional structural schematic view from a first perspective of forming a semi-floating gate according to some embodiments of the present disclosure.

As shown in FIG. 10, based on FIG. 9, the at least part of the first gate material 2211 and the at least part of the second gate material 2221 may be removed, a remaining first gate material 2211 may be served as the first gate 221, and a remaining second gate material 2221 may be served as the second gate 222. The semi-floating gate 220 may include the first gate 221 and the second gate 222.

In some embodiments, since when the contact window K is formed, at least part of the isolation structures 110 exposed by the contact window K may be further removed, a width K1 of the second gate 222 of the semi-floating gate 220 in the first direction may be greater than a width K2 of the first gate.

In some embodiments, when the semi-floating gate 220 is formed, at least part of the isolation structures 110 exposed by a corresponding one of the second trenches 102 may be further removed. That is, at least part of a sidewall of the isolation structure 110 may be removed, such that in the first direction, the width K1 of the second gate 222 of the semi-floating gate 220 may be greater than the width K2 of the first gate 221.

In some embodiments, at least part of the isolation structures 110 may be further removed from the top, such that a top surface of the semi-floating gate 220 may be higher than a top surface of the isolation structure 110 exposed by a corresponding one of the second trenches 102.

In some embodiments, a first isolation layer 300 may be formed at sidewalls of each of the second trenches 102, and an inter-gate dielectric layer 230 and a control gate 240 may be formed in each of the second trenches 102.

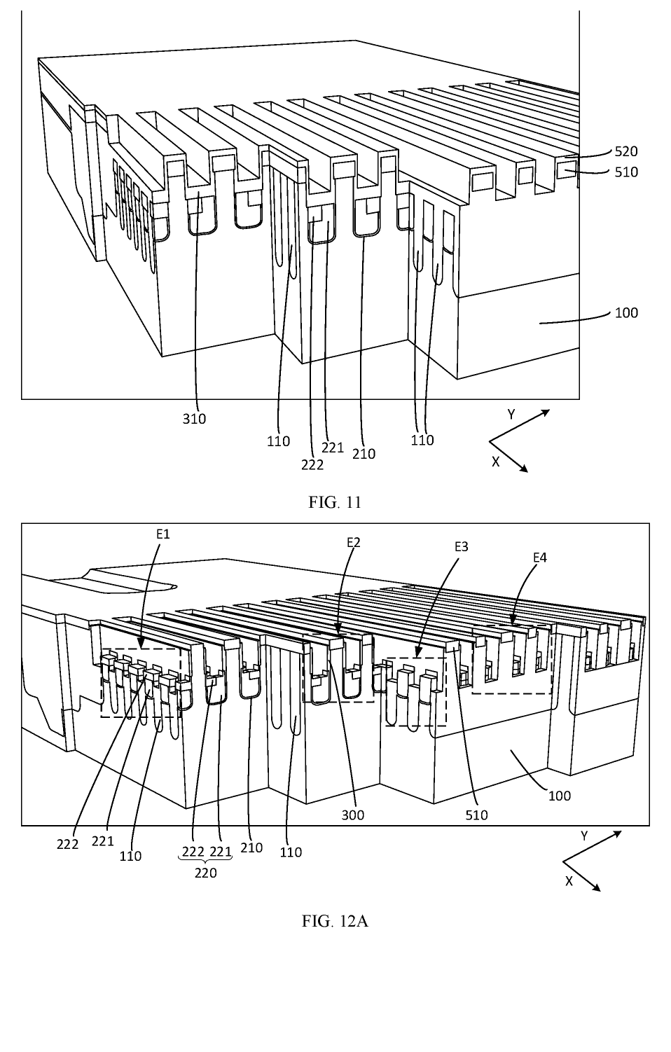

As shown in FIG. 11, FIG. 11 is a three-dimensional structural schematic view from a first perspective of forming a first isolation layer according to some embodiments of the present disclosure.

As shown in FIG. 11, based on FIG. 10, a first isolation layer 300 may be formed, and the sidewalls of each of the second trenches 102 may be covered.

In some embodiments, a first isolation material 310 may be formed in each of the second trenches 102, and the semi-floating gate 220 and the sidewalls of each of the second trenches 102 may be covered. A material of the first isolation material 310 may be an oxide material, such as silicon oxide.

In some embodiments, the first isolation material 310 disposed above the semi-floating gate 220 may be removed, and an inter-gate dielectric layer 230 and a control gate 240 may be formed.

First, the first isolation material 310 disposed above the semi-floating gate 220 may be removed.

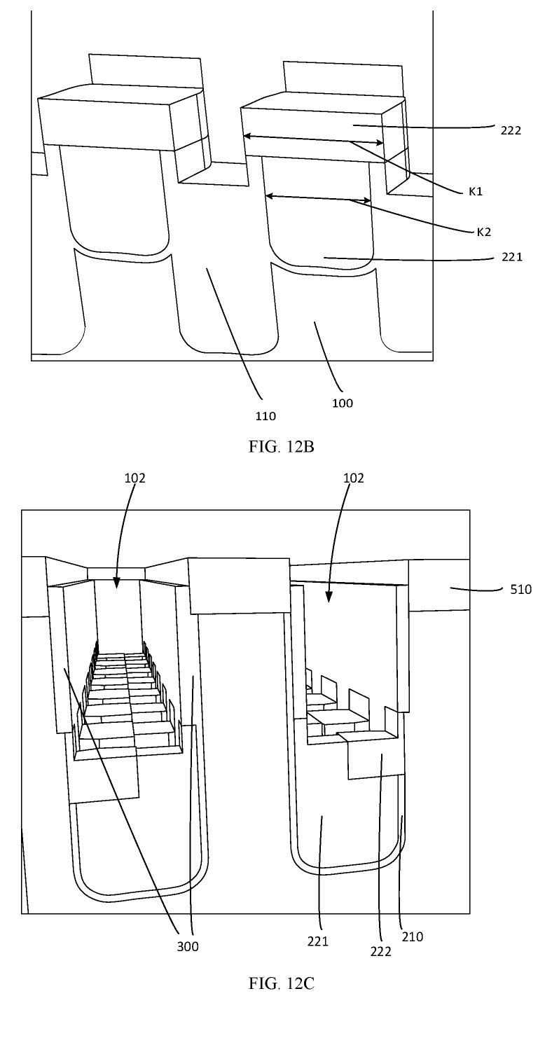

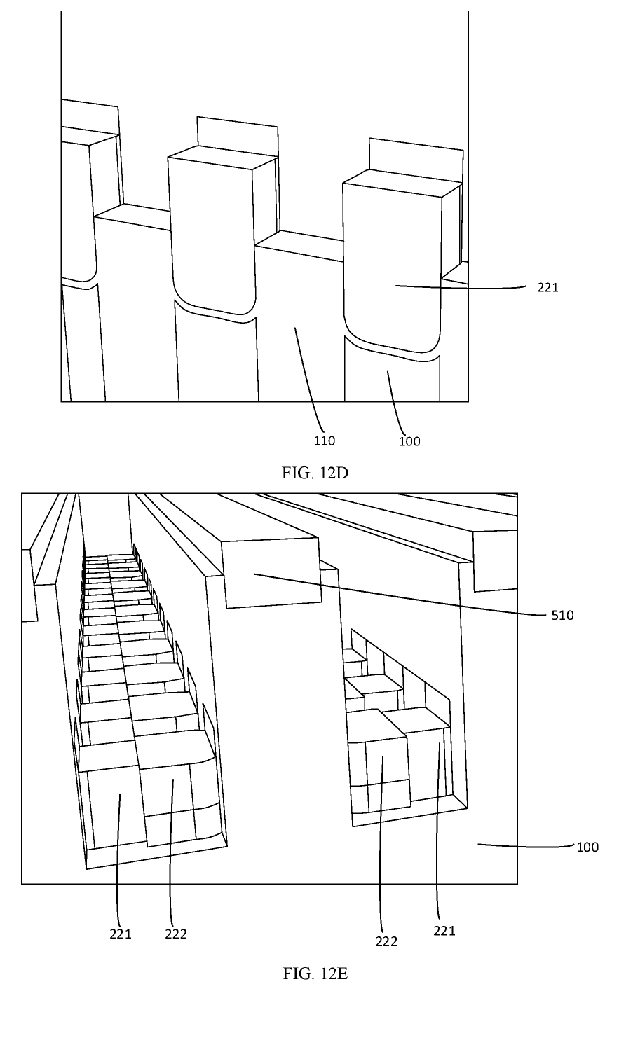

As shown in FIGS. 12A, 12B, 12C, 12D and 12E, FIG. 12A is a three-dimensional structural schematic view from a first perspective of an embodiment of removing the first isolation material above the semi-floating gate in the present disclosure. FIG. 12B is a schematic structural view of a first region of FIG. 12A in the present disclosure. FIG. 12C is a schematic structural view of a second region of FIG. 12A in the present disclosure. FIG. 12D is a schematic structural view of a third region of FIG. 12A in the present disclosure. FIG. 12E is a schematic structural view of a fourth region of FIG. 12A in the present disclosure.

As shown in FIGS. 12A, 12B, 12C, 12D and 12E, a first region shown in FIG. 12B may be E1. A second region shown in FIG. 12C may be E2. A third region shown in FIG. 12D may be E3. A fourth region shown in FIG. 12E may be E4. The first isolation material 310 disposed above the semi-floating gate 220 and disposed at a bottom of each of the second trenches 102 may be removed, and the first isolation material 310 remained at the sidewalls of each of the second trench 102 may be served as the first isolation layer 300, such that the semi-floating gate 220 disposed at the bottom of each of the second trenches 102 may be exposed.

In some embodiments, a first sub-dielectric layer 510 and a second sub-dielectric layer 520 may be further formed on the semiconductor substrate 100, and the second sub-dielectric layer 520 may be an oxide layer. Therefore, when the first isolation layer 300 is formed, that is, when the isolation material disposed above the semi-floating gate 220 is removed, the second sub-dielectric layer 520 may be removed at the same time, and the first sub-dielectric layer 510 may be retained.

In some embodiments, when the first isolation material 310 disposed above the semi-floating gate 220 is removed, at least part of the semi-floating gate 220 may be also removed, such that at least part of the semi-floating gate 220 may be remained at a sidewall of a trench, and the trench may be corresponding to the removed at least part of semi-floating gate 220.

In order to more clearly illustrate that a width K2 of the first gate 221 in the first direction may be less than a width K1 of the second gate 222 in the first direction, a top view may be provided by the embodiments of the present disclosure.

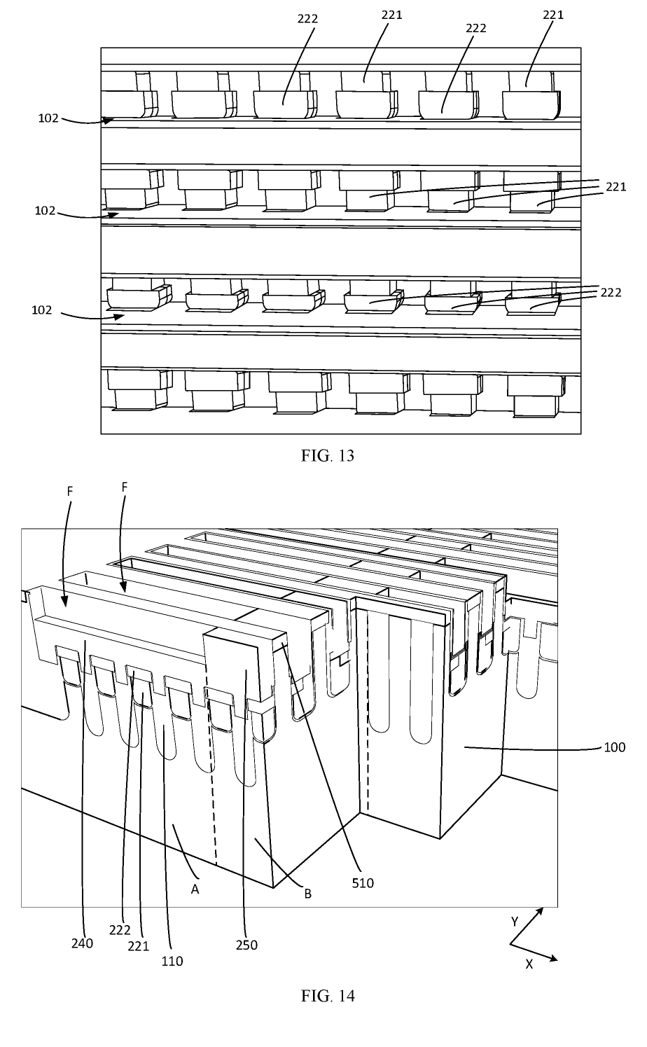

As shown in FIG. 13, FIG. 13 is a top view shown in FIG. 12A according to some embodiments of the present disclosure.

As shown in FIG. 13, a plurality of second trenches 102 may extend along the first direction. Below each of the second trenches 102, a plurality of semi-floating gates 220 may be arranged at intervals in the first direction. Each of the semi-floating gates 220 may have a wide portion and a narrow portion. The wide portion may be the second gate 222, and the narrow portion may be the first gate 221. That is, the gate structure 200 may include the first gate 221 and the second gate 222. In the first direction, the width K2 of the first gate 221 may be less than the width K1 of the second gate.

Then, an inter-gate dielectric layer 230 and a control gate 240 may be formed.

As shown in FIG. 14, FIG. 14 is a three-dimensional structural schematic view from a first perspective of forming an inter-gate dielectric layer and a control gate according to some embodiments of the present disclosure.

As shown in FIG. 14, based on FIG. 13, an inter-gate dielectric layer 230 may be formed.

In some embodiments, the inter-gate dielectric layer 230 may have an ON structure, i.e., a double-layer structure including an oxide layer and a nitride layer.

In some embodiments, a third gate material 241 may be formed, such that the inter-gate dielectric layer 230 may be covered and the corresponding one of the second trenches 102 may be filled. At least part of the third gate material 241 disposed in the memory region A may be served as the control gate 240, and the third gate material 241 disposed in the lead-out region B may be served as the lead-out line 250.

In some embodiments, the lead-out line 250 may be connected to the plurality of control gates 240 disposed in the same row along the first direction.

In some embodiments, at least part of the third gate material 241 disposed in the memory region A may be removed, and a first spare region F may be formed. A third gate material 241 remained in the corresponding one of the second trenches 102 defined in the memory region A may be served as the control gate 240. That is, a height of the third gate material 241 disposed in the memory region A may be reduced to form the control gate 240.

In some embodiments, at least part of the third gate material disposed in the memory region A may be removed, and the first spare region F may be formed. The third gate material disposed in the lead-out region B may be retained. A remaining third gate material disposed in the memory region A may be served as the control gate 240, and the third gate material disposed in the lead-out region B may be served as the lead-out line 250.

In some embodiments, a second isolation layer 400 may be formed in the first spare region F.

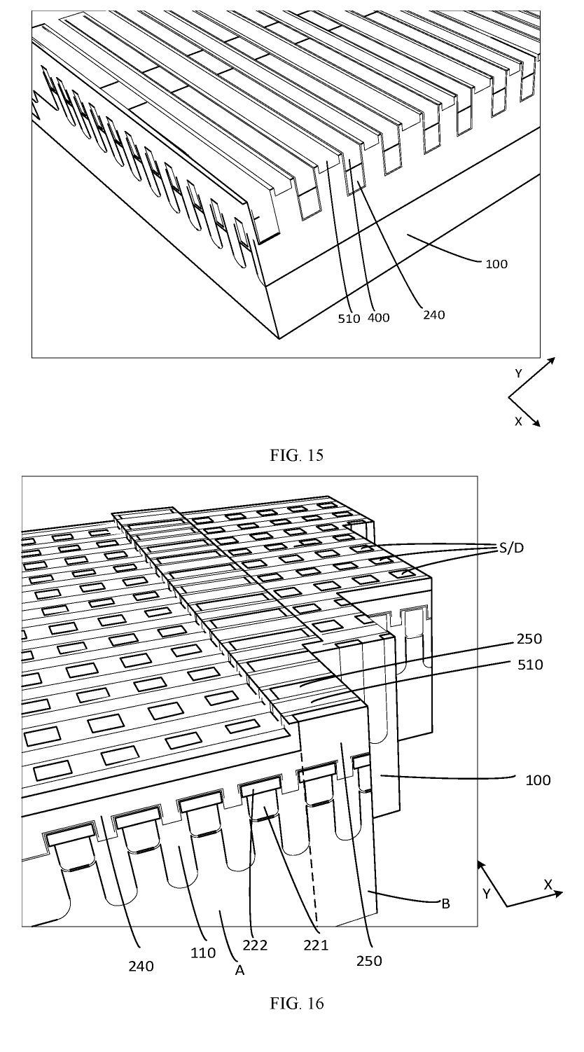

As shown in FIG. 15, FIG. 15 is a three-dimensional structural schematic view from a first perspective of forming a second isolation layer according to some embodiments of the present disclosure.

As shown in FIG. 15, based on FIG. 14, a second isolation layer 400 may be formed disposed in the first spare region F of the memory region A, such that the control gate 240 disposed in the memory region A may be covered, and the second isolation layer 400 may be in contact with the lead-out line 250 disposed in the lead-out region B.

A material of the second isolation layer 400 may be an oxide material, which may be silicon oxide.

In some embodiments, the second isolation layer 400 may be formed in the first spare region F, and the second isolation layer 400 may be disposed on the control gate 240, and the control gate 240 may be disposed in the corresponding one of the second trenches 102 arranged in the memory region A. In some embodiments, a bottom surface of the second isolation layer 400 may be lower than the top surface of the semiconductor substrate 100.

In some embodiments, at least part of the first sub-dielectric layer 510 and at least part of the second isolation layer 400, which are disposed in the memory region A, may be further removed, such that it may be possible to expose the semiconductor substrate 100 disposed in the memory region A.

As shown in FIG. 16, FIG. 16 is a three-dimensional structural schematic view from a fourth perspective of removing at least part of a first sub-dielectric layer and at least part of the second isolation layer in the memory region according to some embodiments of the present disclosure.

As shown in FIG. 16, based on FIG. 15, at least part of the first sub-dielectric layer 510 and at least part of the second isolation layer 400 disposed in the memory region A may be removed, such that it may be possible to expose the semiconductor substrate 100 disposed in the memory region A. The semiconductor substrate 100 disposed in the memory region A may be covered by the first sub-dielectric layer 510. Therefore, after the first sub-dielectric layer 510 is removed, the semiconductor substrate 100 disposed in the memory region A may be exposed, and at least part of the second isolation layer 400 may be removed synchronously, such that a top surface of a remaining second isolation layer 400 and the top surface of the semiconductor substrate 100 may be disposed on the same plane. The first sub-dielectric layer 510 disposed in the lead-out region B may be retained, that is, the first sub-dielectric layer 510 may exist between adjacent two of the plurality of lead-out lines 250 disposed in the lead-out region B.

In some embodiments, a source/drain may be formed in the semiconductor substrate.

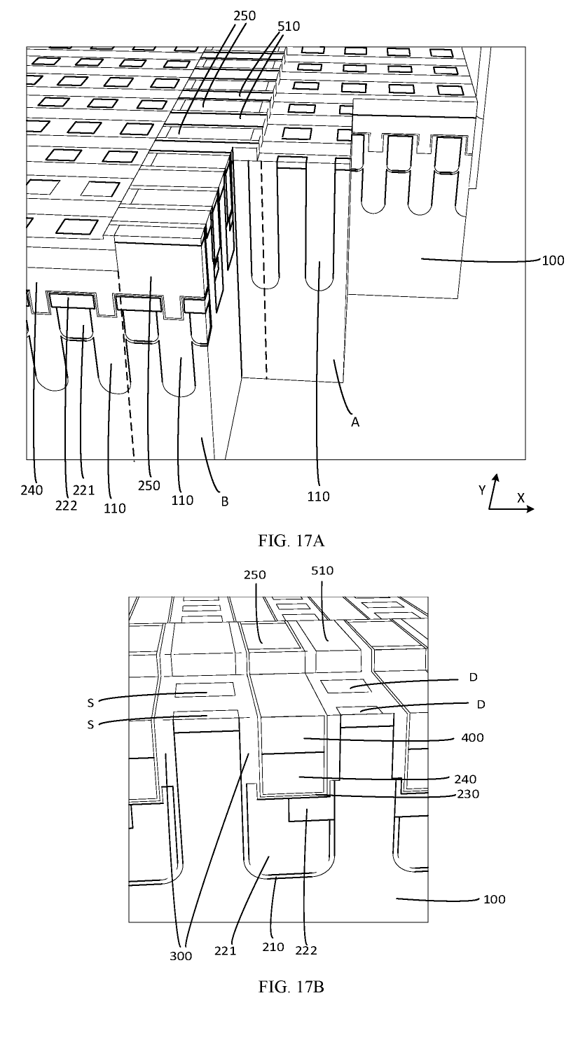

As shown in FIGS. 17A and 17B, FIG. 17A is a three-dimensional structural schematic view from a first perspective of forming source/drain according to some embodiments of the present disclosure, and FIG. 17B is a schematic view from a second perspective of FIG. 17A according to some embodiments of the present disclosure.

As shown in FIGS. 17A and 17B, based on FIG. 16, a source/drain S/D may be formed on a surface of an exposed semiconductor substrate 100 disposed in the memory region A. That is, the source/drain S/D may be formed in the semiconductor substrate 100 disposed at two sides of the gate structure 200 in the second direction. A metal silicide may be formed on the source/drain S/D to reduce the contact resistance. That is, the source/drain S/D may be formed in the semiconductor substrate 100 disposed at two sides of the corresponding one of the first trenches 101 in the second direction.

A side close to the contact window K may be the drain D, and another side may be the source S. In some embodiments, a metal silicide may also be formed on the surface of the lead-out line 250.

A transistor may be further provided by some embodiments of the present disclosure.

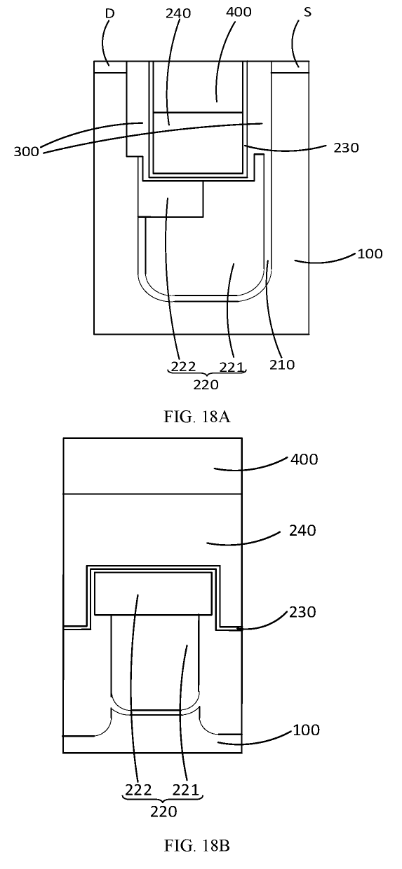

As shown in FIGS. 18A and 18B, FIG. 18A is a schematic structural view from a first perspective of a transistor according to some embodiments of the present disclosure, and FIG. 18B is a schematic structural view from a second perspective of the transistor according to some embodiments of the present disclosure.

As shown in FIGS. 18A and 18B, the transistor 20 may include: a semiconductor substrate 100; a gate insulating layer 210 and a semi-floating gate 220, arranged in the semiconductor substrate 100; an inter-gate dielectric layer 230 and a control gate 240, arranged in the semiconductor substrate 100 and disposed above the semi-floating gate 220, where the control gate 240 may be isolated from the semi-floating gate 220 by the inter-gate dielectric layer 230; and a first isolation layer 300, disposed at sidewalls of the control gate 240. In a second direction, a width of the control gate 240 may be less than a width of a semi-floating gate 220.

In some embodiments, the transistor 20 may include the semiconductor substrate 100, and a first trench 101 may be defined in the semiconductor substrate 100. The gate insulating layer 210 and the semi-floating gate 220 may be arranged in the first trench 101. A second sub-trench 1021 may be defined in the semiconductor substrate 100. The second sub-trench 1021 may be disposed above the first trench 101, and the second sub-trench 1021 may be in communication with the first trench 101. The first isolation layer 300 may be disposed at sidewalls of the second sub-trench 1021. The inter-gate dielectric layer 230 and the control gate 240 may be arranged in the second sub-trench 1021. In a second direction, a width of the control gate 240 may be less than a width of a semi-floating gate 220.

It may be understood that the second sub-trench 1021 may be a part of the second trench 102 disposed in the memory device 10. That is, the second trench 102 disposed in the memory device 10 may include a plurality of second sub-trenches 1021 in the first direction, i.e., in the memory device 10, control gates 240 of a plurality of transistors 20 disposed in the same row along the first direction may be connected to each other.

In some embodiments, the semi-floating gate 220 may include a first gate 221 and a second gate 222. The first gate 221 may be isolated from the semiconductor substrate 100 by the gate insulating layer 210. The second gate 222 may be in contact with the semiconductor substrate 100. In the first direction, a width of the second gate 222 may be greater than a width of the first gate 221.

In some embodiments, the gate insulating layer 210 may be arranged in the first trench 101. The first gate 221 and the second gate 222 may be arranged on the gate insulating layer 210. The first gate 221 may be isolated from the semiconductor substrate 100 by the gate insulating layer 210, and the second gate 222 may be in contact with the semiconductor substrate 100. The second gate 222 may be in contact with the first gate 221. The semi-floating gate 220 may include the first gate 221 and the second gate 222. In the first direction, the width of the second gate 222 may be greater than the width of the first gate 221. It may be understood that the material of the first gate 221 may be different from that of the second gate 222. In some embodiments, the first gate 221 may be made of a polycrystalline material, and the second gate 222 may be made of a single-crystal material.

In some embodiments, the transistor 20 may further include a second isolation layer 400. The second isolation layer 400 may be arranged on the control gate 240 disposed in the second sub-trench 1021. The second isolation layer 400 may be in contact with the control gate 240. A bottom surface of the second isolation layer 400 may be lower than a top surface of the semiconductor substrate 100.

In some embodiments, the transistor 20 may further include a plurality of source/drain S/D. The source/drain S/D may be arranged in an active area C1 disposed at two sides of the gate structure 200 in the second direction. That is, the source/drain S/D may be arranged in the semiconductor substrate disposed at the two sides of the control gate 240 in the second direction, i.e., a corresponding one of the source/drain S/D may be arranged in the semiconductor substrate 100 disposed at the two sides of the first trench 101 in the second direction. For example, the source may be S, and the drain may be D.

In the embodiments, the first isolation layer may be disposed at the sidewalls of the corresponding one of the second trenches, such that the width of the control gate may be less than the width of the semi-floating gate. Therefore, it may be possible to ensure the distance between the control gate and the source/drain, such that it may be possible to effectively reduce leakage and breakdown between the control gate and the source/drain. In addition, on the premise of ensuring the distance and reducing leakage, instead of increasing a thickness of an inter-gate dielectric layer to ensure a certain distance between the control gate and the source/drain, it may be possible to ensure a thickness of the inter-gate dielectric layer to be relatively thinner, such that it may be possible to maintain a coupling rate of the memory device, thereby improving the performance of the memory device.

The above is only an implementation of the present disclosure, not to limit the scope of the present disclosure. Any equivalent structure or equivalent process transformation made by using the content of the specification and the accompanying drawings of the present disclosure, or directly or indirectly applied in other related technical fields, are included in the scope of the present disclosure in the same way.

What is claimed is:

1. A memory device, comprising:
a semiconductor substrate, comprising a memory region;
a plurality of first trenches, defined in the semiconductor substrate;
a gate insulating layer and a semi-floating gate, arranged in a corresponding one of the first trenches;
a plurality of second trenches, defined in the semiconductor substrate, wherein each of the second trenches is disposed above multiple first trenches, and each of the second trenches is in communication with multiple first trenches disposed in a same row along a first direction;
a first isolation layer, arranged at sidewalls of a corresponding one of the second trenches; and
an inter-gate dielectric layer and a control gate, arranged in the corresponding one of the second trenches in the memory region;
wherein in a second direction, a width of the control gate is less than a width of the semi-floating gate.

2. The memory device according to claim 1, wherein the semiconductor substrate further comprises a lead-out region, and the gate insulating layer and the semi-floating gate are arranged in the corresponding one of the first trenches disposed in the lead-out region; and
the inter-gate dielectric layer and a lead-out line are arranged in the corresponding one of the second trenches disposed in the lead-out region, a top surface of the lead-out line is higher than the top surface of the semiconductor substrate in the memory region, and the lead-out line is connected to a plurality of control gates disposed in the same row along the first direction.

3. The memory device according to claim 2, further comprising: a first sub-dielectric layer, arranged on the semiconductor substrate disposed at two sides of the lead-out line, wherein a top surface of the first sub-dielectric layer and the top surface of the lead-out line are disposed on a same plane; and
wherein a plurality of lead-out lines disposed along a second direction are isolated from each other by the first sub-dielectric layer.

4. The memory device according to claim 1, further comprising: a second isolation layer, arranged on the control gate disposed in the corresponding one of the second trenches in the memory region, wherein the second isolation layer is in contact with the control gate, and a bottom surface of the second isolation layer is lower than a top surface of the semiconductor substrate.

5. The memory device according to claim 1, wherein a plurality of isolation structures are arranged in the semiconductor substrate, and the plurality of isolation structures extend along a second direction, such that the semiconductor substrate comprises a plurality of active areas.

6. The memory device according to claim 5, wherein a plurality of semi-floating gates disposed in the same row along the first direction are isolated from each other by the plurality of isolation structures, and a top surface of each of the semi-floating gates is higher than the top surface of each of the isolation structures disposed in the multiple first trenches.

7. The memory device according to claim 1, wherein each of the semi-floating gate comprises a first gate and a second gate;
the first gate is isolated from the semiconductor substrate by the gate insulating layer, the second gate is in contact with the semiconductor substrate, and the second gate is in contact with the first gate; and
in a first direction, a width of the second gate is greater than a width of the first gate.

8. The memory device according to claim 1, further comprising: a plurality of source/drain, arranged in the semiconductor substrate disposed at two sides of the corresponding one of the first trenches along a second direction.

9. A manufacturing method of a memory device, comprising:
providing a semiconductor substrate, wherein the semiconductor substrate comprises a memory region;
forming a plurality of first trenches and a plurality of second trenches, wherein the plurality of first trenches and the plurality of second trenches are disposed in the semiconductor substrate, each of the second trenches is disposed above multiple first trenches, and each of the second trenches is in communication with multiple first trenches disposed in a same row along a first direction;
forming a gate insulating layer and a semi-floating gate in each of the first trenches; and
forming a first isolation layer at sidewalls of each of the second trenches, and forming an inter-gate dielectric layer and a control gate in each of the second trenches;
wherein in a second direction, a width of the control gate is less than a width of the semi-floating gate.

10. The manufacturing method according to claim 9, wherein the forming a plurality of first trenches and a plurality of second trenches, comprises:
forming a plurality of third trenches, wherein the plurality of third trenches are formed in the semiconductor substrate, an isolation structure is formed in each of the third trenches, and the plurality of third trenches extend along a second direction;
removing at least part of the isolation structure and at least part of the semiconductor substrate to form the plurality of second trenches and the plurality of first trenches, wherein multiple first trenches disposed in the same row along the first direction are isolated from each other by a plurality of isolation structures.

11. The manufacturing method according to claim 9, wherein the forming a gate insulating layer and a semi-floating gate in each of the first trenches, comprises:
forming the gate insulating layer at sidewalls of each of the first trenches;
forming a first gate material in each of the first trenches where the gate insulating layer is formed;
removing at least part of the first gate material and at least part of the gate insulating layer to form a contact window, and forming a second gate material above the contact window; and
removing at least part of the first gate material and at least part of the second gate material to form the semi-floating gate, wherein a remaining first gate material is served as a first gate, a remaining second gate material is served as a second gate, and the semi-floating gate comprises the first gate and the second gate.

12. The manufacturing method according to claim 11, wherein in a case where the semi-floating gate is formed, the method further comprises:
removing at least part of the isolation structure exposed by a corresponding one of the second trenches, and a top surface of the semi-floating gate being higher than a top surface of the isolation structure exposed by the corresponding one of the second trenches;
wherein in the first direction, a width of the isolation structure exposed by the corresponding one of the second trenches is less than a width of the isolation structure disposed in the semiconductor substrate, such that a width of the second gate formed in each of the first trenches is greater than a width of the first gate.

13. The manufacturing method according to claim 9, wherein the forming a first isolation layer at sidewalls of each of the second trenches, and forming an inter-gate dielectric layer and a control gate in each of the second trenches, comprises:
forming a first isolation material, and covering the sidewalls of each of the second trenches and the semi-floating gate;
removing the first isolation material disposed above the semi-floating gate in the second trenches, and using the first isolation material remained at the sidewalls of each of the second trenches as the first isolation layer;
forming the inter-gate dielectric layer, wherein the inter-gate dielectric layer is in contact with the semi-floating gate;
forming a third gate material, and covering the inter-gate dielectric layer; and
reducing a height of the third gate material disposed in the memory region to form the control gate.

14. The manufacturing method according to claim 9, wherein the semiconductor substrate further comprises a lead-out region, and the gate insulating layer and the semi-floating gate are formed in the corresponding one of the first trenches disposed in the lead-out region; and
the inter-gate dielectric layer and a lead-out line are formed in the corresponding one of the second trenches disposed in the lead-out region, a top surface of the lead-out line is higher than the top surface of the semiconductor substrate in the memory region, and the lead-out line is connected to a plurality of control gates disposed in the same row along the first direction.

15. The manufacturing method according to claim 9, further comprising:
forming a source/drain in the semiconductor substrate disposed at two sides of a corresponding one of the first trenches along a second direction.

16. The manufacturing method according to claim 9, further comprising:
forming a second isolation layer, wherein the second isolation layer is disposed in each of the second trenches defined in the memory region, and the second isolation layer is disposed above the control gate, and a bottom surface of the second isolation layer is lower than a top surface of the semiconductor substrate.

17. A transistor, comprising:
a semiconductor substrate;
a gate insulating layer and a semi-floating gate, arranged in the semiconductor substrate;
an inter-gate dielectric layer and a control gate, arranged in the semiconductor substrate and disposed above the semi-floating gate, wherein the control gate is isolated from the semi-floating gate by the inter-gate dielectric layer; and
a first isolation layer, arranged at sidewalls of the control gate;
wherein in a second direction, a width of the control gate is less than a width of the semi-floating gate.

18. The transistor according to claim 17, wherein the semi-floating gate comprises a first gate and a second gate;
the first gate is isolated from the semiconductor substrate by the gate insulating layer, the second gate is in contact with the semiconductor substrate, and the second gate is in contact with the first gate; and
in a first direction, a width of the second gate is greater than a width of the first gate.

19. The transistor according to claim 17, further comprising:
a second isolation layer, arranged on the control gate, wherein the second isolation layer is in contact with the control gate, and a bottom surface of the second isolation layer is lower than a top surface of the semiconductor substrate.

20. The transistor according to claim 17, further comprising:
a source/drain, arranged in the semiconductor substrate disposed at two sides of the control gate in a second direction.
